(19) United States
(12) Patent Application Publication
(10) Pub. No.: US 2007/0034909 A1
(43) Pub. Date: Feb. 15, 2007

(54) Nanometer-scale semiconductor devices and method of making

(76) Inventors: James Stasiak, Lebanon, OR (US); Jennifer Wu, Corvallis, OR (US); David E. Hackleman, Monmouth, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/586,254

(22) Filed: Oct. 24, 2006

Related U.S. Application Data
(63) Continuation of application No. 10/668,558, filed on Sep. 22, 2003.

(51) Int. Cl. H01L 29/80

(52) U.S. Cl. 257/273

(57) ABSTRACT

A semiconductor device including a substrate having a dopant of a first polarity, a first semiconducting structure including a dopant of a second polarity disposed over the substrate, and having substantially planar top and side surfaces. The semiconductor device includes a first junction, formed between the first semiconducting structure and the substrate, having an area wherein at least one lateral dimension is less than about 75 nanometers.

### BACKGROUND

### Description of the Art

Over the past few years, the demand for ever cheaper and lighter weight portable electronic devices has led to a growing need to manufacture durable, lightweight, and low cost electronic circuits of increasing complexity, including high density memory chips. To a large extent, over the past thirty years, this growth has been fueled by a nearly constant exponential increase in the capabilities of microelectronic devices; producing unprecedented advances in computational, telecommunication, and signal processing capabilities. In turn, this increase in complexity has driven a corresponding decrease in the feature size of integrated circuit devices, which has typically followed “Moore's Law.” However, the continued decrease in feature size of integrated circuits, into the nanometer regime, has become increasingly more difficult, and may be approaching a limit, because of a combination of physical and economic reasons.

Prior proposed solutions to the problem of constructing nanometer-scale devices have typically fallen into two broad categories, one general area can be described as new patterning techniques, the other general area involves new materials having nanometer-scale dimensions. New patterning techniques include both projection systems utilizing radiation, and direct write systems utilizing particle beams, or scanning probes. Some of the newer higher resolution projection systems require expensive radiation sources such as synchrotrons. On the other hand direct write systems, typically, require a serial process of individually writing each structure in contrast to exposing many structures at one time utilizing projection systems. Thus, direct write systems, typically, have a much lower throughput when compared to projection systems again leading to either increased complexity in manufacturing or increased cost or both.

Recently new materials having semiconducting properties and nanometer-scale dimensions have been synthesized and fabricated into nanometer-scale devices. However, after these nanometer-scale materials are formed, they are often randomly arranged, either one end randomly attached to a substrate or both ends free. This randomness along with the difficulty of physically manipulating nanometer-sized components presents a significant challenge to the fabrication of reproducible and practical nanometer-scale devices.

If these problems persist, the continued growth, seen over the past several decades, in cheaper, higher speed, higher density, and lower power integrated circuits used in electronic devices will be impractical.

### BRIEF DESCRIPTION OF THE DRAWINGS

FIG. 1 is a perspective view of a semiconductor junction according to an embodiment of the present invention;

FIG. 2a is a perspective view of a bipolar junction transistor according to an embodiment of the present invention;

FIG. 2b is a perspective view of a Schottky diode clamped bipolar junction transistor according to an alternate embodiment of the present invention;

FIG. 3 is a perspective view of a bipolar junction transistor according to an alternate embodiment of the present invention;

FIG. 4a is a perspective view of a bipolar junction transistor according to an alternate embodiment of the present invention;

FIG. 4b is a perspective view of a bipolar junction a Schottky diode clamped bipolar junction transistor according to an alternate embodiment of the present invention;

FIG. 5a is a perspective view of an array of bipolar junction transistors according to an embodiment of the present invention;

FIG. 5b is a cross-sectional view of one of the bipolar junction transistors from the array shown in FIG. 5a according to an embodiment of the present invention;

FIG. 5c is a perspective view of an array of diodes according to an embodiment of the present invention;

FIG. 5d is a perspective view of an array of bipolar junction transistors according to an alternate embodiment of the present invention;

FIG. 6 is an exemplary flow chart of a process used to create a semiconductor junction according to an embodiment of the present invention;

FIG. 7 is an exemplary flow chart of a process used to create a bipolar junction transistor according to an embodiment of the present invention;

FIGS. 8a-8h are exemplary cross-sectional views of various processes used to create embodiments of the present invention;

FIGS. 9a-9j are exemplary cross-sectional views of various processes used to create embodiments of the present invention;

FIG. 10 is block diagram of a semiconductor device incorporated in an integrated circuit with control circuitry according to an alternate embodiment of the present invention;

FIG. 11 is a block diagram of an alternate embodiment of the present invention incorporated into an electronic device.

### DESCRIPTION OF THE PREFERRED EMBODIMENTS

The invention provides for the design and fabrication of semiconductor junctions and bipolar junction transistors having nanometer scale junction dimensions. The present invention does not require a process for physically aligning an array of semiconductor nanowires, formed ex-situ, over an array of previously physically aligned nanowires to fabricate a diode or bipolar junction transistor. The present invention allows both the material and dopant to be optimized for each layer providing a process for optimizing the diode or bipolar transistor performance.

It should be noted that the drawings are not true to scale. Further, various parts of the active elements have not been drawn to scale. Certain dimensions have been exaggerated in relation to other dimensions in order to provide a clearer illustration and understanding of the present invention.

In addition, although some of the embodiments illustrated herein are shown in two dimensional views with various regions having depth and width, it should be clearly understood that these regions are illustrations of only a portion of a device that is actually a three dimensional structure. Accordingly, these regions will have three dimensions, including length, width, and depth, when fabricated on an actual device. Moreover, while the present invention is illustrated by embodiments directed to active devices, it is not intended that these illustrations be a limitation on the scope or applicability of the present invention. It is not intended that the active devices of the present invention be limited to the physical structures illustrated. These structures are included to demonstrate the utility and application of the present invention to presently preferred embodiments.

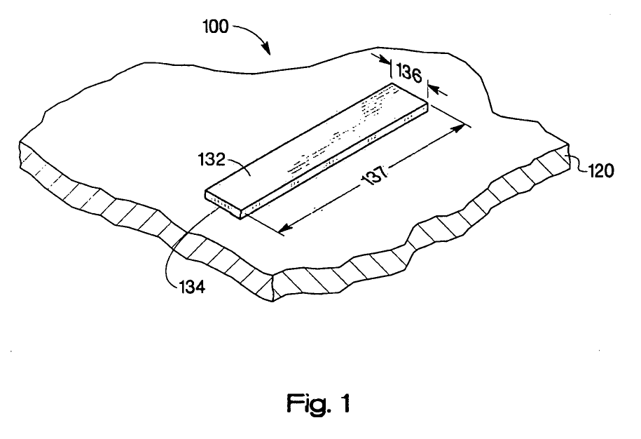

FIG. 1 is an illustration of an exemplary embodiment of the present invention in the form of a semiconductor junction. Substrate 120, and first semiconducting structure 132 form diode 100. In this embodiment, substrate 120 is a semiconductor wafer including a dopant of a first polarity that is either p or n doped at a specified concentration. The particular dopant material and the dopant concentration will depend on various factors, such as the junction dimensions as well as the particular application in which the device will be used. In this embodiment, first semiconducting structure 132 is an epitaxial layer, however, in alternate embodiments, diode 100 may utilize, for example, seimconducting structures formed from polycrystalline or amorphous layers. First semiconducting structure 132 includes a dopant of a second polarity (e.g. a complementary dopant to that of substrate 120), and may be formed from a semiconducting thin film disposed over substrate 120 using conventional semiconductor processing equipment. In this embodiment, first semiconducting structure 132 has substantially planar top and side surfaces, however, in alternate embodiments, other structures may also be utilized. In this embodiment, first structure 132 has a thickness in the range from about 1.0 nanometer to about 75 nanometers. In alternate embodiments, first structure 132 may have a thickness in the range from about 1.0 nanometers to 1,000 nanometers. First structure 132 is doped using a dopant of opposite polarity as that used in substrate 120, wherein opposite polarity is defined in terms of acceptor and donor dopants being opposite in polarity (e.g. the dopant of a first polarity may be n and then the dopant of the second polarity is p). The interface between epitaxial structure 132 and substrate 120 forms first junction 134 having either a pn or np junction, depending on the particular dopant utilized in substrate 120. In addition, junction 134 includes an area formed by length 137 and width 136 wherein at least one lateral dimension is less than about 75 nanometers. According to alternate embodiments, semiconducting junction 134 has an area wherein at least one lateral dimension is less than about 50 nanometers. Preferably junction 134 has an area defined at the interface of less than about 15,000 square nanometers and more preferably less than about 5,000 square nanometers. Semiconducting junction 134 provides on the order of 10 Tera devices/cm², and depending on the particular application in which the device will be used, the areal density of devices, in alternate embodiments, may range from about 0.2 Tera devices/cm² to about 10.0 Tera devices/cm².

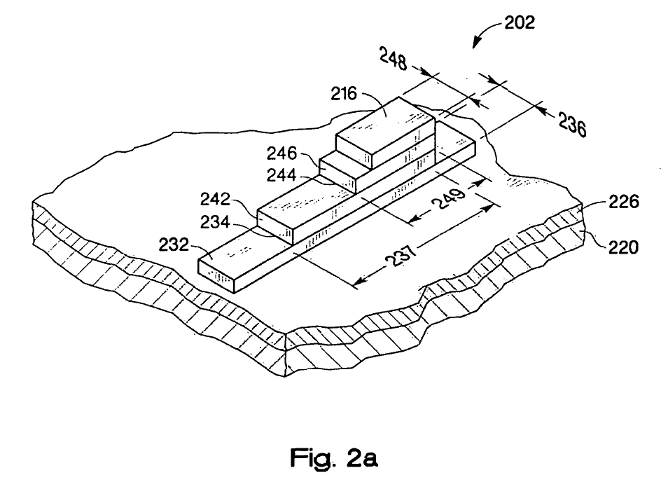

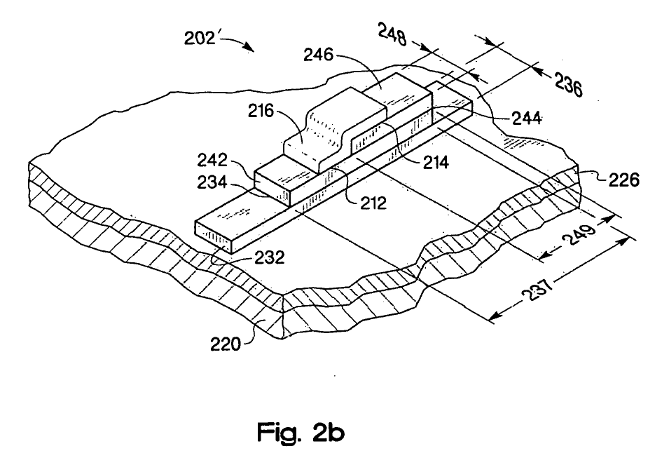

FIG. 2a is an illustration of an exemplary embodiment of the invention in the form of bipolar junction transistor 202 formed by first semiconducting layer 232, base epitaxial semiconducting layer 242, and second semiconducting layer 246 all disposed over substrate 220. In this embodiment, substrate 220 is a conventional silicon semiconductor wafer with dielectric layer 226 disposed between substrate 220 and semiconducting layers 232, 242, and 246. Dielectric layer 226 may include, for example, a buried oxide layer or a semiconductor on insulator structure. In alternate embodiments, substrate 220 may be any of a wide range of materials, such as, gallium arsenide, germanium, glass, sapphire, and indium phosphide to name a few examples.

Epitaxial thin films are utilized to create semiconducting layers 232, 242, and 246, and are formed using conventional semiconductor processing equipment. First semiconducting layer 232 includes a specified dopant and dopant concentration and is formed between substrate 220 and base epitaxial semiconducting layer 242. The particular dopant material and the dopant concentration will depend on various factors, such as the junction dimensions as well as the particular application the device will be used in. Base epitaxial semiconducting layer 242, or the epitaxial semiconducting base layer used to form the base structure, includes a dopant of a first polarity, that is of opposite polarity as that used in first semiconducting layer 232. First semiconducting layer 232 includes a dopant of a second polarity. In this embodiment, base epitaxial layer 242 has a thickness in the range from about 1.0 nanometer to about 75 nanometers. In alternate embodiments, base epitaxial layer 242 may have a thickness in the range from about 1.0 nanometers to 1,000 nanometers. The interface between first semiconducting layer 232 and base epitaxial layer 242 forms first semiconducting junction 234 having either a pn or np junction depending on the particular dopant utilized in first semiconducting layer 232. In addition, first junction 234 includes an area formed by length 237 and width 236 wherein at least one lateral dimension is less than about 75 nanometers. In alternate embodiments, first junction 234 has an area wherein at least one lateral dimension is less than about 50 nanometers. Preferably first junction 234 has an area defined at the interface of less than about 15,000 square nanometers and more preferably less than about 5,000 square nanometers.

Second semiconducting junction 244 is formed between base epitaxial semiconducting layer 242 and second semiconducting layer 246. Second semiconducting layer 246 has the same dopant polarity as that of first semiconducting layer 232 and is formed over base epitaxial semiconducting layer 242. However, second semiconducting layer 246 may have a different dopant material as compared to first semiconducting layer 232 as well as a differing dopant concentration. Second junction 244 includes an area formed by length 249 and width 248 wherein at least one lateral dimension is less than about 75 nanometers. In alternate embodiments, second junction 244 has an area wherein at least one lateral dimension is less than about 50 nanometers. Preferably, second junction 234 has an area defined at the interface of less than about 15,000 square nanometers and more preferably less than about 5,000 square nanometers. In this embodiment, bipolar junction transistor 202 forms a vertically aligned bipolar transistor. In addition, in this embodiment, the base, collector and emitter elements can be doped to the appropriate levels individually. For example, first semiconducting layer 232 may be p doped forming the emitter of the bipolar transistor and the collector (i.e. second semiconducting layer 246) heavily p doped (i.e. p++) with an n doped base (i.e. base epitaxial layer 242) forming a pnp bipolar transistor, thus, providing a structure for optimizing the transistor performance. In addition, in an alternate embodiment first semiconducting layer 232 and base epitaxial layer 242 may be utilized to form a diode similar to that described in FIG. 1. Further, first and second epitaxial semiconducting layers 232 and 246 as well as base epitaxial layer 244, in alternate embodiments, may utilize any combination of semiconducting layers. The first and second layers, for example, may be created from a polycrystalline layer and the base layer from an epitaxial layer. Another example is where the first layer may be created from an epitaxial layer with the base layer created from a polycrystalline layer and the second layer from an amorphous layer.

Electrical contact 216 is formed over a portion of second semiconducting layer 246 to provide electrical routing of signals utilized by the electronic device in which bipolar transistor 202 is located. Electrical contacts to epitaxial layer 232 and base epitaxial layer 242 have not been shown. In addition, in alternate embodiments, electrical contact 216 may be formed from an electrically conductive layer wherein electrical contact 216 forms Schottky barrier 214 to second epitaxial structure 246 and the electrically conductive layer further forms ohmic contact 212 to a portion of base epitaxial semiconducting layer 242 forming Schottky diode clamped bipolar junction transistor 202′ as shown in FIG. 2b. Such a Schottky diode clamped bipolar junction transistor may also be formed, in still other embodiments, by utilizing the electrically conductive layer to form an ohmic contact to a portion of base epitaxial semiconducting layer 242 and a Schottky barrier contact to a portion of first semiconducting layer 232.

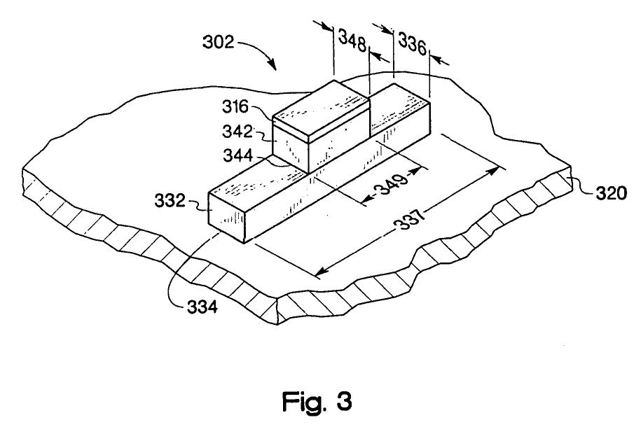

FIG. 3 is an illustration of an alternate embodiment of the invention in the form of bipolar junction transistor 302 comprising doped semiconductor wafer 320, first semiconducting structure 332, and second semiconducting structure 342. In this embodiment, substrate 320 is a semiconductor wafer, is either p or n doped, and forms either the emitter or collector of bipolar junction transistor 302. In this embodiment, substrate 320 is a conventional doped wafer having a specified dopant and dopant concentration wherein the dopant is designated as a dopant of a first polarity. The particular dopant material and the dopant concentration will depend on various factors, such as the junction dimensions as well as the particular application in which the device will be used. Substrate 320, in alternate embodiments, may be any of a wide range of semiconductor materials, such as silicon, gallium arsenide, germanium, and indium phosphide to name a few examples.

A semiconducting thin film is disposed on substrate 320 using conventional semiconductor processing equipment. The semiconducting thin film is utilized to create first semiconducting structure 332 having substantially planar top and side surfaces. In this embodiment, first semiconducting structure 332 is an epitaxial semiconducting layer, however, alternate embodiments, may utilize any of the widely available semiconducting layers such as amorphous or polycrystalline layers to form the semiconducting thin film. First structure 332 is doped using a dopant of opposite polarity (e.g. complementary dopant), as that used in substrate 320 and is designated a dopant of a second polarity. The interface between first structure 332 and substrate 320 forms first semiconducting junction 334 having either a pn or np junction depending on the particular dopant utilized in substrate 320. In addition, first junction 334 includes an area formed by length 337 and width 336 wherein at least one lateral dimension, in the plane formed by junction 334 is less than about 75 nanometers. In alternate embodiments, first junction 334 has an area wherein at least one lateral dimension is less than about 50 nanometers. In alternate embodiments, first junction 334 has an area defined at the interface of less than about 15,000 square nanometers and more preferably less than about 5,000 square nanometers.

Second semiconducting junction 344 is formed between second semiconducting structure 342 and first structure 332. Second semiconducting structure 342 has the same dopant polarity as that of substrate 320 (e.g. a dopant of the first polarity). However, second semiconducting structure 342 may have a different dopant material as compared to substrate 320 as well as a differing dopant concentration. In this embodiment, second semiconducting structure 342 is formed from a polycrystalline thin film formed on first semiconducting structure 332. Second semiconducting structure 342 has substantially planar top and side surfaces. In addition, in alternate embodiments, second semiconducting structure 342 may utilize an amorphous or epitaxial thin film. Second junction 344 includes an area formed by length 349 and width 348 wherein at least one lateral dimension is less than about 75 nanometers. In alternate embodiments, second junction 344 has an area wherein at least one lateral dimension is less than about 50 nanometers. In still other embodiments, second junction 344 has an area defined at the interface of less than about 15,000 square nanometers and more preferably less than about 5,000 square nanometers.

In addition, in this embodiment, the base, collector and emitter elements can be doped to the appropriate levels individually. For example, the wafer may be p doped forming the emitter of the bipolar transistor and the collector (i.e. second structure 342) heavily p doped (i.e. p++) with an n doped base (i.e. first structure 332) forming a pnp bipolar transistor, providing a process for optimizing the transistor performance. Electrical contact 316 is formed over a portion of second semiconducting structure 342 to provide electrical routing of signals utilized by the electronic device in which bipolar transistor 302 is located. Electrical contacts to first structure 332 and substrate 320 have not been shown.

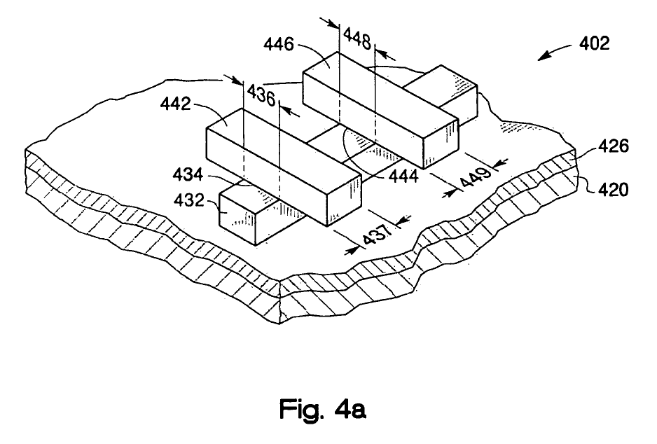

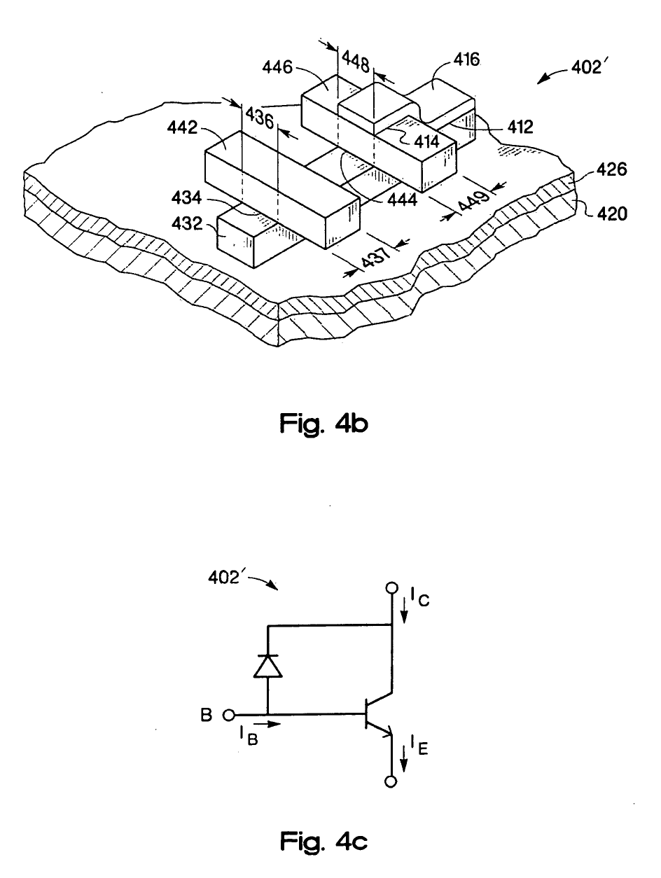

An alternate embodiment of the present invention is shown in an perspective view in FIG. 4a. In this embodiment, epitaxial semiconducting structure 432, first polycrystalline semiconducting structure 442, and second polycrystalline semiconducting structure 446 form bipolar junction transistor 402. Epitaxial semiconducting structure 432, first polycrystalline semiconducting structure 442, and second polycrystalline semiconducting structure 446 have substantially planar top and side surfaces. Epitaxial semiconducting structure 432, including a dopant, is formed on dielectric layer 426 that is disposed over substrate 420. The epitaxial semiconducting thin film, utilized to create epitaxial semiconducting structure 432, as well as dielectric layer 426, are created using conventional semiconductor processing equipment. In this embodiment, substrate 420 is a conventional silicon wafer with a silicon dioxide layer formed on the wafer as dielectric layer 426. Substrate 420, in alternate embodiments, may be any of a wide range of materials, gallium arsenide, germanium, sapphire, and glass are just a few examples. The particular material utilized will depend on various factors, such as the junction dimensions and the particular application in which the transistor will be used. The particular dopant material and the dopant concentration of epitaxial semiconducting structure 432, also, will depend on various factors, such as the junction dimensions as well as the particular application in which the device will be used.

Polycrystalline semiconducting structure 442 and second polycrystalline semiconducting structure 446 are formed over epitaxial structure 432. Polycrystalline structures 442 and 446 each include a dopant of opposite polarity than that of epitaxial structure 432 (e.g. structures 442 and 446 may be p doped and then epitaxial structure 432 is n doped). In this embodiment, polycrystalline structures 442 and 446 may have differing dopant materials. In addition, polycrystalline structures 442 and 446 may also have differing dopant concentrations. In utilizing various combinations of dopant materials and concentrations the performance of the bipolar junction transistor 402 may be optimized. Further, in an alternate embodiment, first polycrystalline semiconducting structure 442 and second polycrystalline semiconducting structure 446 can be crystalline semiconducting nanowires grown ex-situ and physically aligned over epitaxial semiconducting structure 432 to also form bipolar junction transistor 402.

The interface between epitaxial structure 432 and polycrystalline structure 442 forms first semiconducting junction 434 having either a pn or np junction depending on the particular dopant utilized in epitaxial structure 432. In addition, first junction 434 includes an area formed by length 437 and width 436 wherein at least one lateral dimension is less than about 75 nanometers. In alternate embodiments, first junction 434 has an area wherein at least one lateral dimension is less than about 50 nanometers. In still other embodiments, first junction 434 has an area defined at the interface of less than about 15,000 square nanometers and more preferably less than about 5,000 square nanometers.

Second semiconducting junction 444 is formed between second polycrystalline semiconducting structure 446 and epitaxial structure 432. Second polycrystalline semiconducting structure 446 has the same dopant polarity as that of first polycrystalline structure 442. Second junction 444 includes an area formed by length 449 and width 448 wherein at least one lateral dimension is less than about 75 nanometers. In alternate embodiments, second junction 444 has an area wherein at least one lateral dimension is less than about 50 nanometers. In still other embodiments, second semiconducting junction 444 has an area defined at the interface of less than about 15,000 square nanometers and more preferably less than about 5,000 square nanometers. Thus, the junctions formed between polycrystalline structures 442, and 446 and epitaxial structure 432 form bipolar junction transistor 402. Bipolar junction transistor 402 provides on the order of 10 Tera transistors/cm². In addition, in this embodiment, the base, collector and emitter elements can be doped to the appropriate levels individually. For example, the polycrystalline structure 442 may be p doped forming the emitter of the bipolar transistor, second polycrystalline structure 446, forming the collector, may be heavily p doped (i.e. p++) with an n doped base forming a pnp bipolar transistor.

Referring to FIG. 4b, an alternate embodiment of the present invention is shown where electrical contact 416 is utilized to form Schottky diode clamped bipolar junction transistor 402′. In this embodiment, electrical contact 416 is formed from an electrically conductive layer wherein electrical contact 416 forms Schottky barrier 414 to second polycrystalline structure 446 and the electrically conductive layer further forms ohmic contact 412 to epitaxial structure 432. Such a Schottky diode clamped bipolar junction transistor may also be formed, in still other embodiments, by utilizing the electrically conductive layer to form an ohmic contact to a portion of epitaxial semiconducting structure 432 and a Schottky barrier contact to a portion of first polycrystalline structure 442.

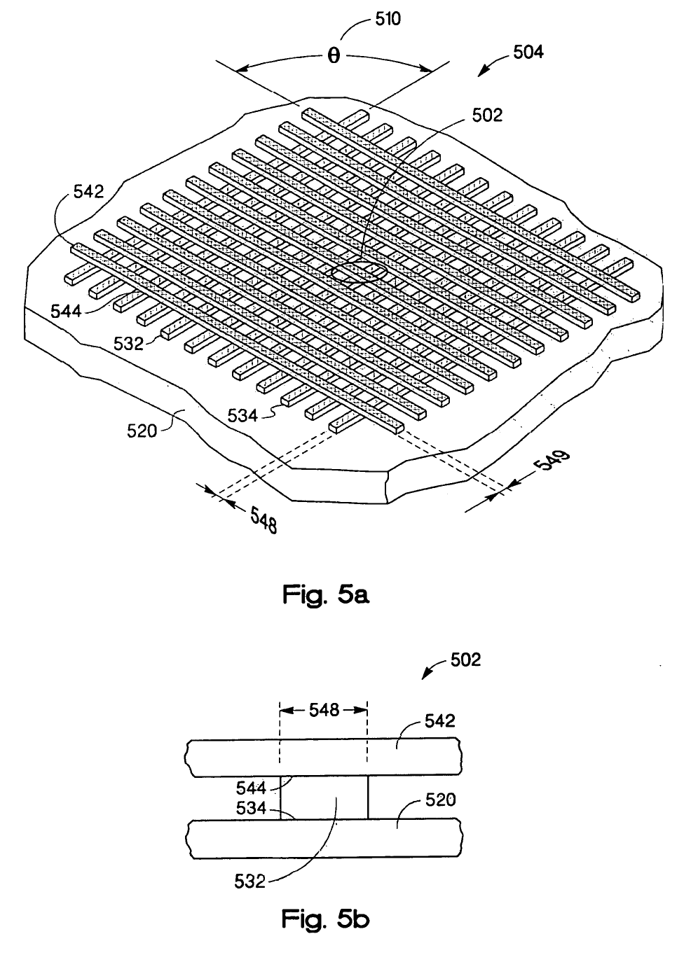

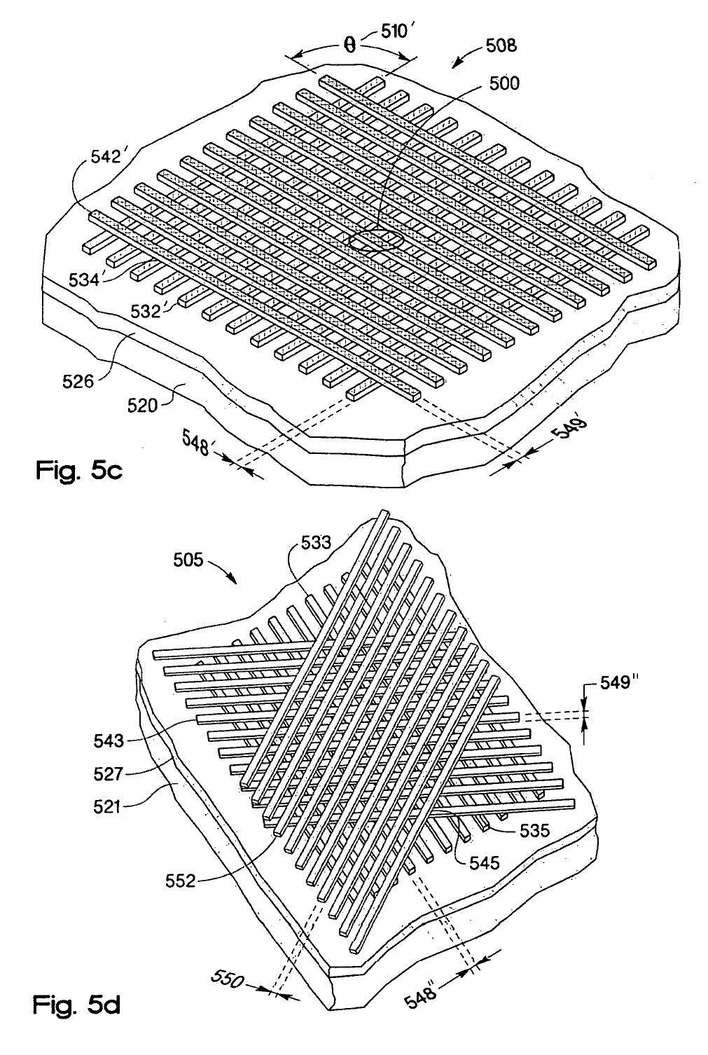

An alternate embodiment of the present invention is shown in a perspective view in FIG. 5a. In this embodiment, a plurality of epitaxial semiconducting base lines 532, a plurality of first semiconducting lines 542 and doped semiconductor wafer 520 form an array of bipolar junction transistors 504. Substrate 520 is a semiconductor wafer, that is either p or n doped at a specified concentration and forms either the emitter or collector of bipolar junction transistor 502 as shown in FIG. 5b. The particular dopant material and the dopant concentration will depend on various factors, such as the junction dimensions as well as the particular application in which the device will be used. The epitaxial thin film, used to create epitaxial semiconducting base lines 532, is formed on substrate 520 using conventional semiconductor processing equipment. Epitaxial semiconducting base lines 532 are substantially parallel to each other and epitaxial base lines 532 are doped using a dopant of opposite polarity as that used in substrate 520. The interface between epitaxial base lines 532 and substrate 520 forms first semiconducting junction 534 having either a pn or np junction depending on the particular dopant utilized in substrate 520. In addition, first junction 534 includes width 548 less than about 75 nanometers as shown in FIGS. 5a and 5b. In alternate embodiments first junction 534 includes width 548 less than about 50 nanometers.

Second semiconducting junction 544 is formed between first semiconducting lines 542 and epitaxial base lines 532. First semiconducting lines 542 have the same dopant polarity as that of substrate 520. The semiconducting thin film, used to create first semiconducting lines 542, is formed on epitaxial base lines 532 using conventional semiconductor processing equipment. In this embodiment first semiconducting lines 542 are polycrystalline semiconducting lines. In alternate embodiments, first semiconducting lines may be formed from other thin films such as amorphous semiconducting thin films. First semiconducting lines 542 are substantially parallel to each other and form a predetermined angle 510 to epitaxial lines 532. In alternate embodiments, angle 510 is between about 20 degrees and about 90 degrees. More preferably angle 510 is about 90 degrees such that first semiconducting lines 542 and epitaxial lines 532 are substantially mutually orthogonal.

Second junction 544 includes an area formed by length 549 shown in FIG. 5a and width 548 shown in FIG. 5b wherein at least one lateral dimension is less than about 75 nanometers. In alternate embodiments, second semiconducting junction 544 has an area wherein at least one lateral dimension is less than about 50 nanometers. In still other embodiments, second semiconducting junction 544 has an area defined at the interface of less than about 15,000 square nanometers and more preferably less than about 5,000 square nanometers. First and second junctions 534 and 544 provides on the order of 10 Tera transistors/cm², and depending on the particular application in which the device will be used, the areal density of devices, in alternate embodiments, may range from about 0.2 Tera transistors/cm² to about 10.0 Tera transistors/cm²

Further, in alternate embodiments epitaxial base lines 532 and first semiconducting lines 542 may each have a length (not shown) greater than about 10 microns. In still other embodiments, epitaxial base lines 532 and first semiconducting lines 542 each may have a length (not shown) greater than about 100 microns. In addition, in this embodiment, the base, collector and emitter elements can be doped to the appropriate levels individually. For example, the wafer can be n-doped forming the emitter of the bipolar transistor and the collector heavily n-doped (i.e. n++) with a p-doped base forming a npn bipolar transistor.

An alternate embodiment of the present invention is shown in a perspective view in FIG. 5c. In this embodiment, a plurality of first semiconducting lines 532′, a plurality of second semiconducting lines 542′ are formed on dielectric layer 526 creating diode array 508. In this embodiment substrate 520′ is a conventional silicon wafer with a silicon dioxide layer formed on the wafer as dielectric layer 526. Substrate 520′, in alternate embodiments, may be any of a wide range of materials, gallium arsenide, germanium, sapphire, and glass are just a few examples. The particular material utilized will depend on various factors, such as the junction dimensions and the particular application in which diode array 508 is utilized.

Semiconducting junction 534′ is formed between first semiconducting lines 532′ and second semiconducting lines 542′ forming diode 500. First semiconducting lines 532′ are doped with a dopant of a first polarity. First semiconducting thin film, utilized to create first semiconducting lines 532′, is formed on substrate 520′ using conventional semiconductor processing equipment and are substantially parallel to each other. Second semiconducting lines 542′ are doped with a dopant of a second polarity and are formed on first semiconducting lines 532′. Second semiconducting lines 542′ are substantially parallel to each other and form a predetermined angle 510′ to first semiconducting lines 532′. In alternate embodiments, angle 510′ is between about 20 degrees and about 90 degrees. In still other embodiments, angle 510′ is about 90 degrees such that second semiconducting lines 542 and first semiconducting lines 532′ are substantially mutually orthogonal.

Semiconducting junction 534′ has length 549′ and width 548′ wherein at least one lateral dimension is less than about 75 nanometers. In alternate embodiments, semiconducting junction 534′ has an area wherein at least one lateral dimension is less than about 50 nanometers. In still other embodiments, junction 534′ has an area defined at the interface of less than about 15,000 square nanometers and more preferably less than about 5,000 square nanometers. Junction 534′ provides on the order of 10 Tera diodes/cm², and depending on the particular application in which the device will be used, the areal density of diodes, in alternate embodiments, may range from about 0.2 Tera diodes/cm² to about 10.0 Tera diodes/cm²

An alternate embodiment of the present invention is shown in a perspective view in FIG. 5d. In this embodiment, a plurality of epitaxial semiconducting lines 533, a plurality of second semiconducting lines 543, and a plurality of third semiconducting lines 552 are formed over dielectric layer 527 creating a hexagonal array of bipolar junction transistors 505. In alternate embodiments, the plurality of epitaxial semiconducting lines 533, of second semiconducting lines 543, and of third semiconducting lines 552 may be formed at a predetermined angle other than 60 similar to that shown in FIG. 5a. In this embodiment, substrate 521 is a conventional silicon wafer with a silicon dioxide layer formed on the wafer as dielectric layer 527. Dielectric layer 527 may include, for example, a buried oxide layer or a semiconductor on insulator structure. Substrate 521, in alternate embodiments, may be any of a wide range of materials, gallium arsenide, germanium, sapphire, and glass are just a few examples. The particular material utilized will depend on various factors, such as the junction dimensions and the particular application in which the array is utilized.

Epitaxial semiconducting lines 533 are either p or n doped having the desired dopant and dopant concentration, and form either the emitter or collector of the bipolar junction transistor. The particular dopant material and the dopant concentration will depend on various factors, such as the junction dimensions as well as the particular application the transistor array will be used in. The epitaxial thin film, used to create epitaxial semiconducting lines 533, is formed on dielectric layer 527 using conventional semiconductor processing equipment. Epitaxial semiconducting lines 533 are substantially parallel to each other. Second semiconducting lines 543 are doped using a dopant of opposite polarity as that used in epitaxial semiconducting lines 533. The interface between epitaxial lines 533 and second semiconducting lines 543 forms first junction 535 having either a pn or np junction depending on the particular dopant utilized in epitaxial semiconducting lines 533. In addition, first junction 535 includes an area formed by a length (not shown) and width 548″ wherein at least one lateral dimension is less than about 75 nanometers. In alternate embodiments, first junction 535 includes an area formed by a length (not shown) and width 548″ wherein at least one lateral dimension is less than about 50 nanometers.

Second semiconducting junction 545 is formed between second and third semiconducting lines 543 and 552. Third semiconducting lines 552 are formed over second semiconducting lines 543, and are doped with a dopant of the same polarity as that used in epitaxial semiconducting lines 533. In this embodiment, second and third semiconducting lines 543 and 552 are polycrystalline lines, however, in other embodiments, other types of semiconductor lines may also be utilized, such as amorphous lines. Second junction 545 includes a length (not shown) and width 549″, wherein at least one lateral dimension is less than about 75 nanometers. In alternate embodiments, second junction 535 includes a length (not shown) and width 549″ less than about 50 nanometers.

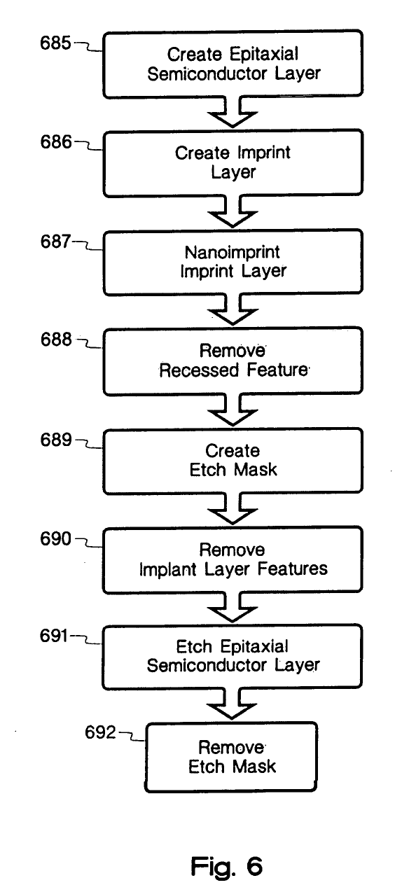

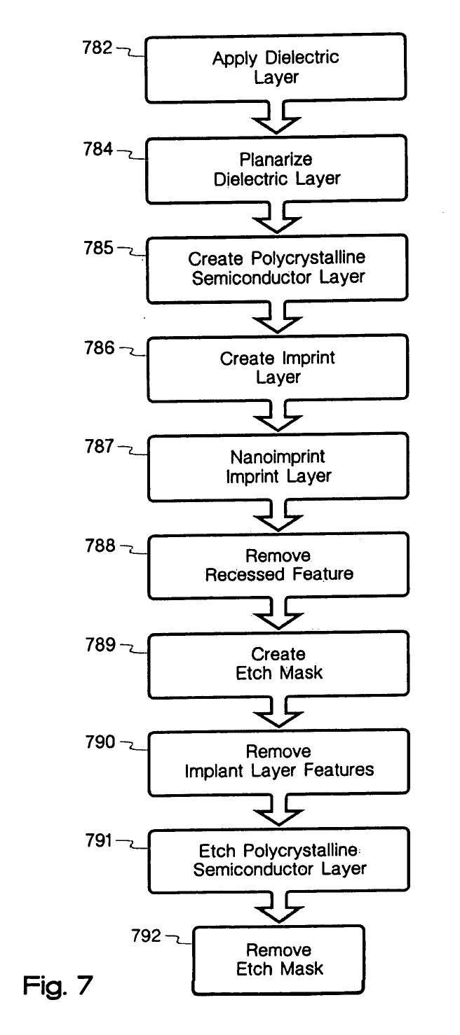

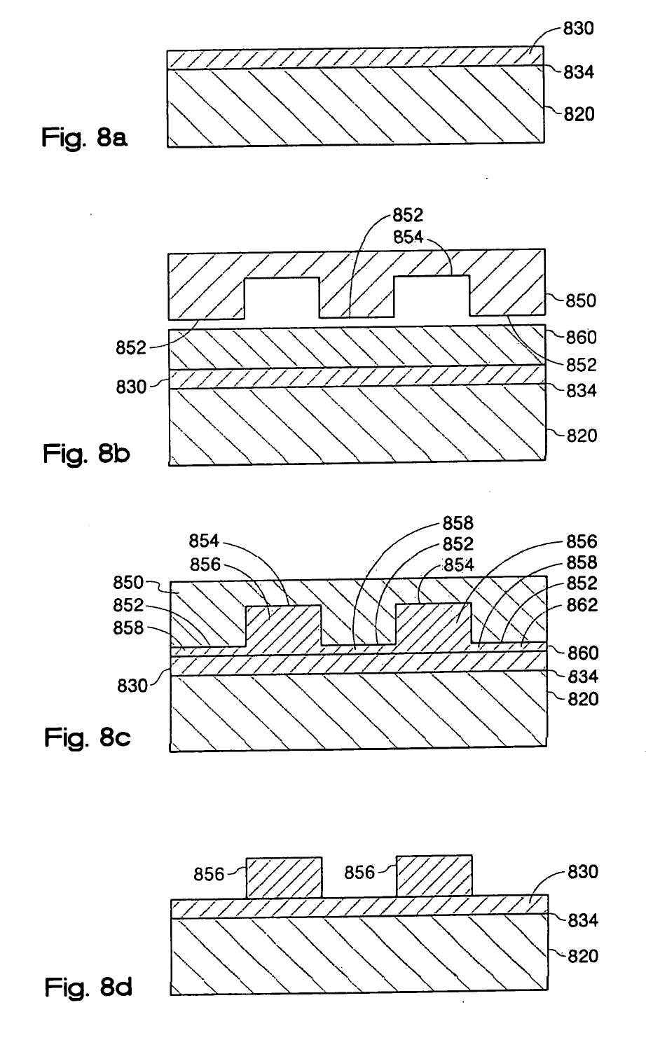

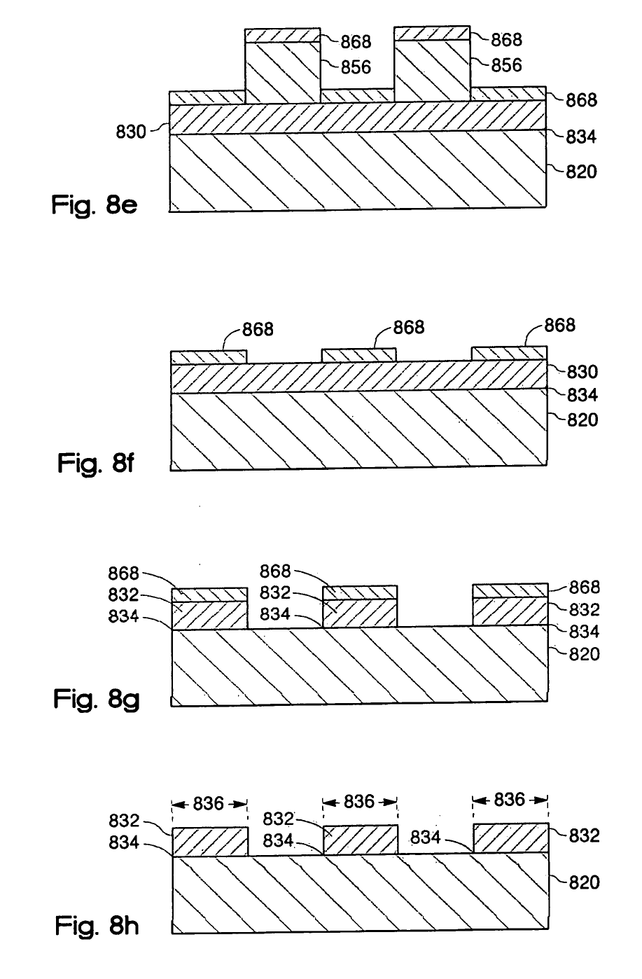

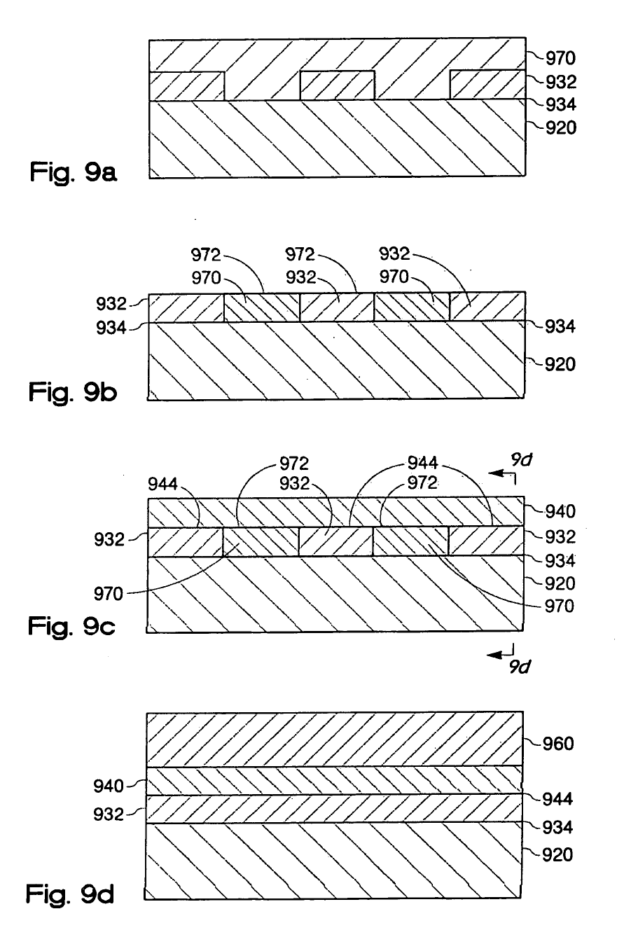

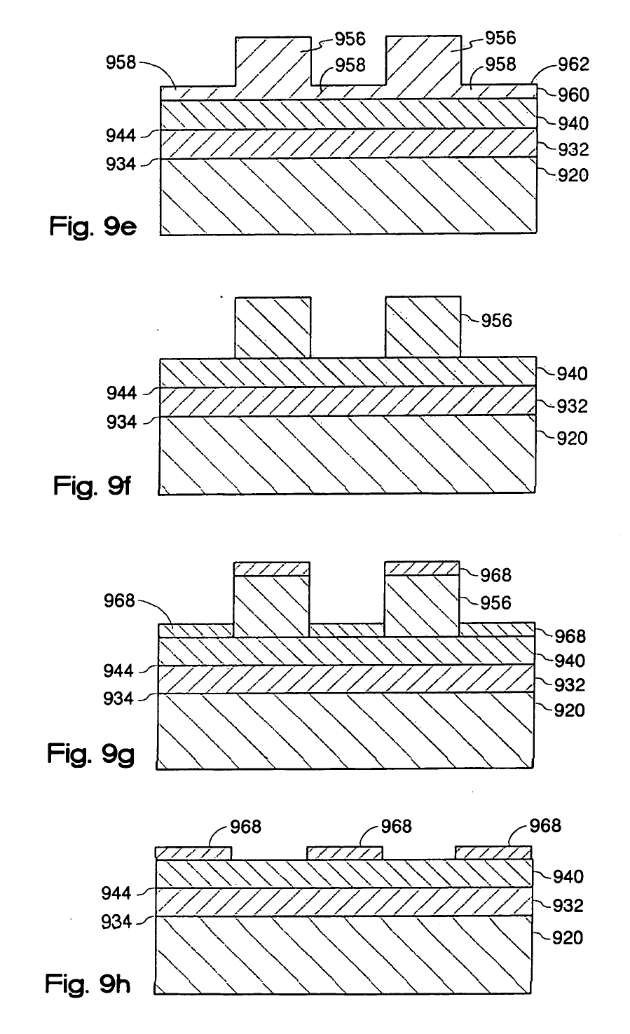

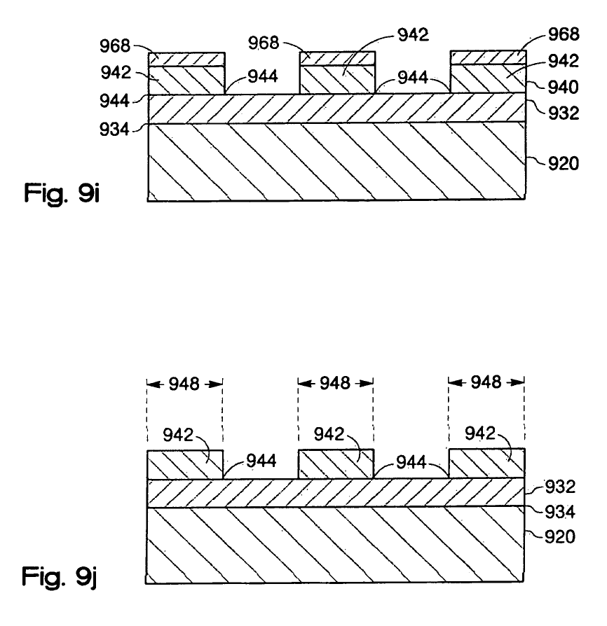

FIGS. 6 and 7 are exemplary process flow charts used to create exemplary embodiments of the invention. FIGS. 8a-8h and 9a-9j are exemplary illustrations of the processes utilized to create a diode or bipolar junction transistor, and are shown only to better clarify and understand the invention. Actual dimensions are not to scale and some features are exaggerated to more clearly point out the process.

Referring to FIG. 8, epitaxial process 685 is utilized to create epitaxial semiconducting layer 830 over doped semiconductor substrate 820 (see FIG. 8a). Epitaxial semiconducting layer 830 includes a dopant of a first polarity, opposite in polarity to the dopant contained in semiconductor substrate 820, forming semiconductor junction 834 (see FIG. 8a). In this embodiment, epitaxial semiconducting layer 830 is an n or p doped epitaxial silicon thin film formed, using conventional semiconductor processing equipment, on a complementary doped silicon wafer having a dopant of opposite polarity to that utilized in the epitaxial layer. In this embodiment, epitaxial semiconducting layer 830 has a thickness in the range from about 1.0 nanometers to about 75.0 nanometers. In alternate embodiments the thickness of the epitaxial layer may range from about 1.0 nanometers to about 1,000 nanometers. And still in other embodiments epitaxial semiconducting layer 830 may be a doped epitaxial silicon layer, which has a thickness less than about 75 nanometers. In alternate embodiments, substrate 820 may be any of a wide range of materials, such as, gallium arsenide, germanium, glass, sapphire, and indium phosphide to name a few examples. In still other embodiments, substrate 820 may also include a dielectric layer formed the substrate and the epitaxial semiconducting layer. In such embodiments the dielectric layer may include, for example, a buried oxide layer or a semiconductor on insulator structure.

Imprint application process 686 is utilized to form or create imprint layer 860 on epitaxial semiconducting layer 830 (see FIG. 8b). The imprint layer may be applied utilizing any of the appropriate techniques such as spin coating, vapor deposition, spray coating or ink jet deposition to name just a few examples. In one embodiment, imprint layer 860 (see FIG. 8b) is a polymethyl methacrylate (PMMA) spin coated onto epitaxial semiconducting layer 830. Imprint layer 860 may be any moldable material. That is any material that either flows or is pliable under a first condition and relatively solid and less pliable under a second condition may be utilized. Examples of non-polymeric materials that may be utilized, for the imprint layer, are metals and metal alloys having melting points below the temperature at which either the substrate or epitaxial layer would be degraded or damaged. Typically, for polymeric imprint layers a low temperature bake process is utilized to drive off any excess solvent that may remain after the layer is applied.

Nanoimprinting process 687 is used to imprint the desired structures or features into imprint layer 860 (see FIG. 8c). Nanoimprinter 850 is pressed or urged toward imprint layer 860 under a condition in which the imprint layer is pliable. For example, heating a PMMA layer above its softening or glass transition temperature. Nanoimprinter 850 (see FIG. 8b) includes features or structures having a substantially complementary shape to that desired to be formed in imprint layer 860. The desired structures of nanoimprinter 850 are represented by protrusions 852 and indentations 854 as shown, in the simplified schematic, in FIG. 8b. By complementary, it is meant that the pattern formed in imprint layer 860 (see FIG. 8c) has a shape corresponding to the complement of the pattern formed in nanoimprinter 850 (see FIG. 8b). That is protrusion 852 on the nanoimprinter forms recessed feature 858 (see FIG. 8c) and indentation 854 forms raised feature 856 (see FIG. 8c). The particular temperature and pressure utilized in nanoimprinting process 687 will depend on various parameters such as the size and shape of the features being molded and the specific materials used for the imprint layer.

Recessed feature removing process 688 is utilized to remove recessed features 858 (see FIG. 8c) formed during nanoimprinting. Recessed feature removing process 688 may be accomplished by any wet or dry etch process appropriate for the particular material utilized for the imprint layer. For example, to remove residual PMMA 862 that forms recessed feature 858 (see FIG. 8c) an oxygen plasma etching process or what is generally referred to as a reactive ion etch can be utilized, exposing the underlying epitaxial semiconductor layer 830 (see FIG. 8d).

Optional etch mask creating process 689 is utilized to deposit optional etch mask 868 (see FIG. 8e) by depositing a thin metal or dielectric layer over the nanoimprinted surface (see FIG. 8e). For example, when epitaxial semiconducting layer 830 is an epitaxial silicon layer, a two layer etch mask may be utilized by first depositing a diffusion barrier material over the surface over portions of imprinting layer 860 and portions of epitaxial semiconducting layer 830. Subsequently an electrical conductor, such as aluminum, may be deposited. The diffusion barrier may be utilized in those applications where the desired electrical conductor acts as a donor dopant in the epitaxial semiconducting layer, such as aluminum and gold in silicon. The particular material utilized as a diffusion barrier depends on various parameters such as the composition of the epitaxial semiconducting layer, the desired second metal, and the particular etching process used to etch the epitaxial semiconducting layer. In addition, the diffusion barrier and second metal can also be utilized to form electrical contacts to the epitaxial semiconducting layer. Etch mask 868 can be formed from any metal, or dielectric material that provides the appropriate selectivity in etching epitaxial semiconducting layer 830. Etch mask 868 is utilized, in embodiments, where the imprint layer would be damaged or degraded in a later etching process used to etch epitaxial semiconducting layer 830.

Optional implant layer removal process 690 is utilized after etch mask 868 (see FIG. 8f) is formed. A selective chemical etch is utilized to remove raised portions 856 (see FIG. 8e) of the imprint layer, causing etch mask material deposited on top of raised portions 856 to be removed. The particular selective chemical etch used will depend on the particular imprint material and etch mask material used. Tetrahydrofuran (THF) may be utilized, as a selective etch for PMMA. Other examples of selective chemical etches for PMMA are ethanol water mixtures, and a 1:1 ratio of isopropanol and methyl ethyl ketone used above 25° C. Preferably, acetone at room temperature in an ultrasonic bath is utilized as a selective etch for PMMA followed by an isopropanol rinse. Another example for PMMA, utilizes a methylene chloride soak for about 10 minutes followed by agitating in methylene chloride in an ultrasonic cleaner for about 1 minute. A plasma clean process can also be utilized, in addition to the selective chemical etch, to further clean the exposed epitaxial semiconductor layer surface and the surface of the etch mask.

Epitaxial semiconductor layer etching process 691 is utilized to etch epitaxial semiconducting layer 830 in removing those selected areas or portions not protected by etch mask 868 to form epitaxial semiconducting structures 832 (see FIG. 8g). Epitaxial semiconductor layer etching process 691 may be accomplished by any wet or dry etch process appropriate for the particular epitaxial semiconductor material as well as the dopant material used. Depending on the particular epitaxial semiconductor material being etched, as well as the particular application in which the device will be used, the etch profile may extend into the substrate 820. For example, CMOS compatible wet etches include tetramethyl ammonium hydroxide (TMAH), potassium or sodium hydroxide (KOH and NaOH), and ethylene diamine pyrochatechol (EDP). Examples of dry etches that can be utilized are fluorinated hydrocarbon gases (CFₓ), xenon difluoride (XeF₂), and sulfur hexafluoride (SF₆).

Etch mask removal process 692 is utilized to remove etch mask 868 (see FIG. 8h). Etch mask removal process 692 may be accomplished by any wet or dry etch process appropriate for the particular material utilized for the etch mask. Depending on the particular material utilized in forming etch mask 868 selected portions of the etch mask may be etched using additional nanoimprinting processes forming electrical contacts in the un-etched areas of the epitaxial semiconductor layer. In one embodiment, after removal of the etch mask, epitaxial semiconductor structure 832 forms semiconductor junction 834 having a length (not shown) and width 836 wherein at least one lateral dimension is less than about 75 nanometers. In other embodiments semiconductor junction 834 has an area wherein at least one lateral dimension less than about 50 nanometers. In still other embodiments, junction 834 has an area defined at the interface of less than about 15,000 square nanometers and more preferably less than about 5,000 square nanometers. Epitaxial semiconducting structures 832 and semiconducting junction 834 provide on the order of up to 10 Tera devices/cm², and depending on the particular application in which the device will be used, the areal density of junctions or diodes, in alternate embodiments, may range from about 0.2 Tera devices/cm² to about 10.0 Tera devices/cm².

If the semiconducting structure 832 is to be further processed, to form a bipolar junction transistor, the process proceeds to the processes used to form a polycrystalline semiconductor layer as shown in FIG. 7. Dielectric application process 782 (see FIG. 9a) is utilized to form or deposit planarizing dielectric layer 970 on the surface of the processed substrate (see FIG. 8h) with the epitaxial semiconductor structure 932. Any of a number of inorganic or polymeric dielectrics may be utilized. For example, silicon dioxide deposited using a plasma enhanced chemical vapor deposition process (PECVD) can be utilized. Other materials such as silicon nitride, silicon oxynitride, polyimides, benzocyclobutenes, as well as other inorganic nitrides and oxides may also be utilized. In addition, other silicon oxide films such as tetraethylorthosilicate (TEOS) and other “spin-on” glasses, as well as glasses formed by other techniques may also be utilized. Dielectric Planarizing process 784 is used to planarize planarizing dielectric layer 970 (see FIG. 9b). For example, dielectric planarizing process 784 may utilize mechanical, resist etch back, or chemical mechanical processes, to form substantially planar surface 972 (see FIG. 9b).

Polycrystalline formation process 785 is utilized to form or create polycrystalline semiconducting layer 940 over semiconducting structures 932 and planarizing dielectric layer 970 on substantially planar surface 972 (see FIG. 9c). Polycrystalline semiconducting layer 940 includes a dopant having the same polarity as the dopant used in semiconductor wafer 920. For those embodiments utilizing a dielectric layer polycrystalline semiconducting layer 940 includes a dopant of opposite polarity as that used in epitaxial semiconductor structure 932. In addition, for those embodiments utilizing a dielectric layer a third semiconductor layer is utilized to form a bipolar transistor. Such a third semiconductor layer and its corresponding structures may be formed utilizing processes similar to those described herein. Epitaxial semiconductor structure 932 and polycrystalline semiconducting layer 940 (see FIG. 9c) form second semiconductor junction 944. For example, polycrystalline semiconducting layer 940 (see FIG. 9c) is an n or p doped polycrystalline silicon thin film, formed using conventional semiconductor processing equipment.

Imprint layer application process 786 is utilized to form or create imprint layer 960 on polycrystalline semiconducting layer 940 (see FIG. 9d). Please note that FIGS. 9d-9j are rotated through ninety degrees compared to FIGS. 9a-9c, however, the structures described in these figures are not limited to this 90 degree angle. Typically, the imprint layer will be the same or similar to that utilized above for creating the epitaxial semiconductor junction utilizing imprint application process 686, however other imprint layer materials may also be utilized. For example, imprint layer 960 (see FIG. 9d) may be a PMMA spin coated film. Imprint layer 960 may be any moldable material applied using any of the techniques discussed above.

Nanoimprinting process 787 is used to imprint the desired structures or features into imprint layer 960 (see FIG. 9e). The nanoimprinter (not shown) is pressed or urged toward imprint layer 960 under a condition in which the imprint layer is pliable forming recessed feature 958 and raised feature 956 in imprint layer 960. Both nanoimprinting process 787 as well as the nanoimprinter may be similar to that discussed above in nanoimprinting process 687. For example, heating the PMMA layer above its softening or glass transition temperature can be utilized.

Recessed removing process 788 is utilized to remove recessed features 958 (see FIGS. 9e and 9f) formed during nanoimprinting. For example, removal of residual PMMA features 962 that form recessed features 958. Recessed removing process 788 may be accomplished by any wet or dry etch process appropriate for the particular material utilized for the imprint layer as discussed above for process 688.

Optional etch mask forming process 789 is utilized to create etch mask 968 by depositing a thin metal layer over the nanoimprinted surface (see FIG. 9g). This process may be accomplished in a similar manner to that discussed above in etch mask forming process 689.

Optional implant layer removal process 790 is utilized to remove raised portions 956 (see FIG. 9g and 9h). Removal process 790 is performed after etch mask 968 is formed, and may be similar to that described for optional implant layer removal process 690.

Polycrystalline semiconductor etching process 791 is utilized to etch polycrystalline semiconductor layer 940 (see FIG. 9i) in those areas not protected by etch mask 968. Etching process 791 forms polycrystalline semiconducting structures 942. In addition etching process 791 may be accomplished by any wet or dry etch process appropriate for the particular polycrystalline semiconductor material as well as the dopant material used. Etching process 791 may be similar to that described for etching process 691.

Etch removal process 792 is utilized to remove etch mask 968 as shown in FIG. 9j. Etch mask removal process 792 may be accomplished by any wet or dry etch process appropriate for the particular material utilized for the etch mask as described for removal process 692. Similar to removal process 692, depending on the particular material utilized in forming etch mask 968, selected portions of the etch mask may be etched using additional nanoimprinting processes to form electrical contacts in the un-etched areas of the polycrystalline semiconductor layer. In addition, in alternate embodiments, when etch mask 968 is an appropriate electrically conductive material etch mask 968 can be utilized to form a Schottky barrier to either polycrystalline semiconducting structure 942 or to substrate 920 as well as forming an ohmic contact to a portion of epitaxial semiconducting structure 932. In this embodiment, semiconductor junctions 934 and 944 form a bipolar junction transistor. In addition, semiconductor junction 944 includes an area formed by a length (not shown) and width 948 wherein at least one lateral dimension is less than about 75 nanometers. In alternate embodiments, semiconductor junction 944 has an area wherein at least one lateral dimension is less than about 50 nanometers. In still other embodiments, junction 944 has an area defined at the interface of less than about 15,000 square nanometers and more preferably less than about 5,000 square nanometers. Semiconducting junction 944 provides on the order of 10 Tera devices/cm², and depending on the particular application in which the device will be used, the areal density of transistors or devices, in alternate embodiments, may range from about 0.2 Tera devices/cm² to about 10.0 Tera devices/cm².

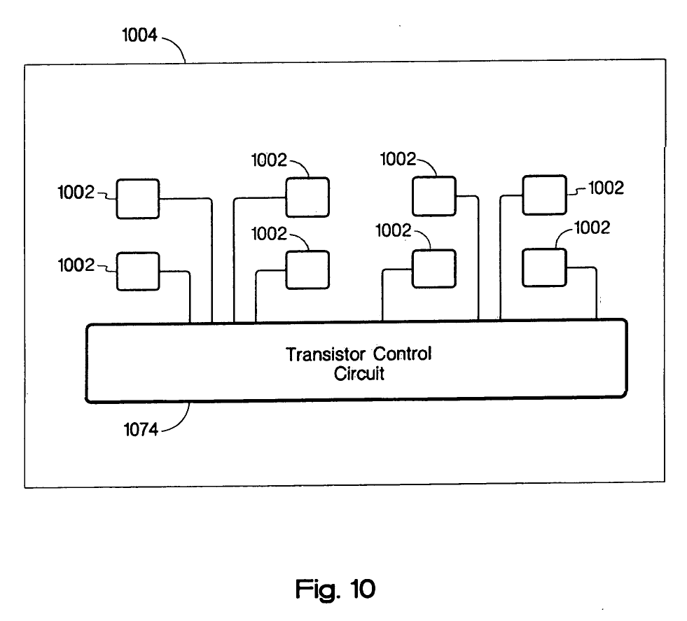

Referring to FIG. 10 an exemplary embodiment of the present invention in the form of an integrated circuit 1004 that has one or more bipolar junction transistors 1002 arranged in an array and controlled by transistor control circuitry 1074. The transistor control circuitry 1074 allows individual control of each bipolar junction transistor 1002. Although FIG. 10 shows only one connection between transistor control circuitry 1074 and transistor 1002 other connections may be made depending on the particular application in which integrated circuit 1004 will be utilized. Integrated circuit 1004 may be fabricated with conventional CMOS, BiCMOS, or custom CMOS/HVCMOS circuitry. The ability to couple the present invention with the use of conventional semiconductor processes the cost is lowered and the ability to mass-produce combined nanoscale devices and circuitry is possible.

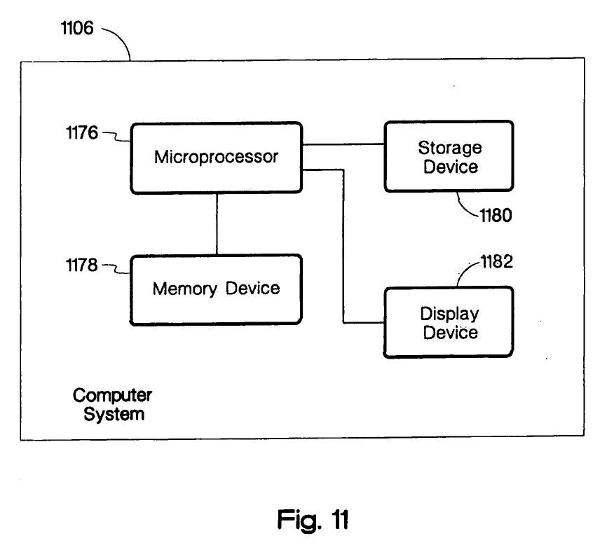

Referring to FIG. 11 an exemplary block diagram of an electronic device 1106, such as a computer system, video game, Internet appliance, terminal, MP3 player, cellular phone, or personal digital assistant to name just a few. Electronic device 1106 includes microprocessor 1176, such as an Intel processor sold under the name “Pentium Processor,” or compatible processor. Many other processors exist and may also be utilized. Microprocessor 1176 is electrically coupled to a memory device 1178 that includes processor readable memory that is capable of holding computer executable commands or instructions used by the microprocessor 1176 to control data, input/output functions, or both. Memory device 1178 may also store data that is manipulated by microprocessor 1176. Microprocessor 1176 is also electrically coupled either to storage device 1180, or display device 1182 or both. Microprocessor 1176, memory device 1178, storage device 1180, and display device 1182 each may contain an embodiment of the present invention as exemplified in earlier described figures and text showing semiconductor junctions, diodes, and bipolar junction transistors that have an area wherein at least one lateral dimension is less than about 75 nanometers. In alternate embodiments, such junctions have an area wherein at least one lateral dimension is less than about 50 nanometers. In still other embodiments, the junctions have an area defined at the interface of less than about 15,000 square nanometers and more preferably less than about 5,000 square nanometers. Such devices provide on the order of 10 Tera devices/cm², and depending on the particular application in which the device will be used, the areal density of transistors or devices, in alternate embodiments, may range from about 0.2 Tera devices/cm² to about 10.0 Tera devices/cm².

What is claimed is:

1. A semiconductor device, comprising:
a substrate including a dopant of a first polarity;
a first semiconducting structure including a dopant of a second polarity and disposed over said substrate, said first semiconducting structure having substantially planar top and side surfaces;
a first junction formed between said first semiconducting structure and said substrate, said first junction having an area having at least one lateral dimension less than about 75 nanometers.

2. The semiconductor device in accordance with claim 1, further comprising:
a second semiconducting structure including a dopant of said first polarity formed on said first semiconducting structure said second semiconducting structure having substantially planar top and side surfaces; and
a second junction formed between said first semiconducting structure and said second semiconducting structure, said second junction having a length and a width, and said second junction having an area having at least one lateral dimension less than about 75 nanometers.

3. The semiconductor device in accordance with claim 1, wherein said first semiconducting structure further comprises a plurality of epitaxial semiconducting base lines substantially parallel to each other, and said first semiconducting structure further comprises a plurality of first semiconducting lines substantially parallel to each other and at a predetermined angle to said plurality of epitaxial semiconducting lines.

4. The semiconductor device in accordance with claim 3, wherein said epitaxial semiconducting lines and said first semiconducting lines form an array of bipolar junction transistors having at least one junction having a junction area having at least one lateral dimension less than about 75 nanometers.

5. A semiconductor device, comprising:
a substrate;
a base epitaxial semiconducting layer including a dopant of a first polarity disposed over said substrate;
a first semiconducting layer including a dopant of a second polarity disposed over said substrate; and
a first junction formed between said base epitaxial semiconducting layer and said first semiconducting layer, said first junction having an area having at least one lateral dimension less than about 75 nanometers.

6. The semiconductor device in accordance with claim 5, further comprising:
a second semiconducting layer including a dopant of said second polarity formed over said base epitaxial semiconducting layer; and
a second junction formed between said epitaxial semiconducting base layer and said second semiconducting layer having a length and a width, and said second junction having an area having at least one lateral dimension less than about 75 nanometers.

7. The semiconductor device in accordance with claim 6, wherein said first semiconducting layer further comprises a first epitaxial semiconducting layer, wherein said base epitaxial semiconducting layer, said first epitaxial semiconducting layer, and said second semiconducting layer form a vertical bipolar transistor.

8. The semiconductor device in accordance with claim 6, further comprising an electrically conductive layer forming an ohmic contact to a portion of said base epitaxial semiconducting layer, and said electrically conductive layer forming a Schottky barrier to a portion of either said first or said second semiconducting layers, whereby a Schottky diode clamped bipolar junction transistor is formed.

9. An integrated circuit comprising:
at least one semiconductor device of claim 6; and
a transistor control circuit coupled to said at least one semiconductor device.

10. The semiconductor device in accordance with claim 5, wherein said substrate further comprises a semiconductor substrate having a dopant of said second polarity, wherein said semiconductor substrate forms said first semiconductor layer.

11. The semiconductor device in accordance with claim 5, wherein said base epitaxial semiconducting layer further comprises a plurality of epitaxial semiconducting base lines substantially parallel to each other, and said first semiconducting layer further comprises a plurality of first semiconducting lines substantially parallel to each other and at a predetermined angle to said plurality of epitaxial semiconducting base lines.

12. The semiconducting device in accordance with claim 11, further comprising a plurality of second semiconducting lines substantially parallel to each other and at a predetermined angle to said plurality of epitaxial semiconducting base lines.

13. The semiconducting device in accordance with claim 11, wherein said substrate further comprises a dielectric layer disposed between said substrate and said epitaxial semiconducting base lines.

14. The semiconducting device in accordance with claim 11, wherein said epitaxial semiconducting base lines and said first and second semiconducting lines form a hexagonal array.

15. The semiconductor device in accordance with claim 11, wherein said plurality of first semiconducting lines are substantially mutually orthogonal to said plurality of epitaxial semiconducting base lines.

16. The semiconductor device in accordance with claim 11, wherein said predetermined angle is between about 20 degrees and about 90 degrees.

17. The semiconductor device in accordance with claim 11, wherein said plurality of first semiconducting lines and said plurality of epitaxial semiconducting base lines form a diode array having an areal density in the range from about 0.2 Tera diodes/cm² to about 10.0 Tera diodes/cm².

18. The semiconductor device in accordance with claim 11, wherein said plurality of first semiconducting lines and said plurality of epitaxial semiconducting base lines form a bipolar junction transistor array having an areal density in the range from about 0.2 Tera transistors/cm² to about 10.0 Tera transistors/cm².

19. The semiconductor device in accordance with claim 5, wherein said first junction further comprises an area of less than about 15,000 square nanometers.

20. The semiconductor device in accordance with claim 5, wherein said substrate further comprises a dielectric layer disposed between said substrate and said base epitaxial semiconducting layer.

21. The semiconductor device in accordance with claim 5, wherein said base epitaxial semiconducting layer further comprises a thickness in the range from about 1.0 nanometer to about 1,000 nanometers.

22. An electronic device, comprising:
an integrated circuit including at least one semiconductor device of claim 5.

23. A computer system, comprising:
a microprocessor;
an electronic device including at least one semiconductor device of claim 5 coupled to said microprocessor; and
memory coupled to said microprocessor, said microprocessor operable of executing instructions from said memory to transfer data between said memory and the electronic device

24. The computer system in accordance with claim 23, wherein said electronic device is a storage device.

25. The computer system in accordance with claim 23, wherein said electronic device is a display device.

26. The computer system in accordance with claim 23, wherein said memory further comprises an integrated circuit including at least one semiconductor device having:
a substrate;
an base epitaxial semiconducting layer including a dopant of a first polarity disposed over said substrate;
a first semiconducting layer including a dopant of a second polarity disposed over said substrate; and
a first junction formed between said base epitaxial semiconducting layer and said first semiconducting layer, said first junction having an area having at least one lateral dimension less than about 75 nanometers.

27. The computer system in accordance with claim 26, wherein said base epitaxial semiconducting layer further comprises a plurality of epitaxial semiconducting base lines substantially parallel to each other, and said first semiconducting layer further comprises a plurality of first semiconducting lines substantially parallel to each other and at a predetermined angle to said plurality of epitaxial semiconducting base lines.

28. The computer system in accordance with claim 23, wherein said microprocessor further comprises an integrated circuit including at least one semiconductor device having:
a substrate;
an base epitaxial semiconducting layer including a dopant of a first polarity disposed over said substrate;
a first semiconducting layer including a dopant of a second polarity disposed over said substrate; and
a first junction formed between said base epitaxial semiconducting layer and said first semiconducting layer, said first junction having an area having at least one lateral dimension less than about 75 nanometers.

29. The computer system in accordance with claim 28, wherein said base epitaxial semiconducting layer further comprises a plurality of epitaxial semiconducting base lines substantially parallel to each other, and said first semiconducting layer further comprises a plurality of first semiconducting lines substantially parallel to each other and at a predetermined angle to said plurality of epitaxial semiconducting base lines.

30. A bipolar junction transistor comprising:
a semiconductor substrate having a substantially planar surface including a dielectric layer formed on or within said substrate;
a first epitaxial semiconducting structure including a dopant of a first polarity disposed on said dielectric layer, said first epitaxial semiconducting structure having an area formed in a plane parallel to said substrate of less than about 15,000 square nanometers;
a second epitaxial semiconducting structure including a dopant of a second polarity formed on said first epitaxial semiconductor structure, said second epitaxial semiconducting structure having an area formed in a plane parallel to said substrate of less than about 15,000 square nanometers;
a third epitaxial semiconducting structure including a dopant of said first polarity formed on said second epitaxial semiconductor structure, said third epitaxial structure having an area formed in a plane parallel to said substrate of less than about 15,000 square nanometers; and
an electrically conductive layer forming an ohmic contact to a portion of said second epitaxial semiconducting structure, and said electrically conductive layer forming a Schottky barrier to a portion of either said first or said third epitaxial semiconducting structures, whereby a Schottky diode clamped bipolar junction transistor is formed.

31. A bipolar junction transistor, comprising:
a semiconductor substrate having a substantially planar surface including a dielectric layer formed on said substrate
an epitaxial semiconducting structure formed on said dielectric layer, said epitaxial structure having an area having at least one lateral dimension less than about 75 nanometers, and forming a base region of the bipolar junction transistor;
a first polycrystalline semiconducting structure, formed on at least a portion of said epitaxial structure, said first polycrystalline structure having an area having at least one lateral dimension less than about 75 nanometers, and forming an emitter region of the bipolar junction transistor; and
a second polycrystalline semiconducting structure formed on at least a portion of said epitaxial structure, said second polycrystalline structure having an area having at least one lateral dimension less than about 75 nanometers, and forming a collector region of the bipolar junction transistor.

32. A diode array, comprising:
a silicon semiconductor wafer;
an insulating layer disposed over said silicon wafer; a plurality of epitaxial semiconducting structures having an area having at least one lateral dimension less than about 75 nanometers, said plurality of epitaxial structures disposed over said insulating layer; and
a plurality of polycrystalline semiconducting structures having an area having at least one lateral dimension less than about 75 nanometers, said plurality of polycrystalline structures in contact with said plurality of epitaxial structures, forming an array of semiconducting junctions.

33. A semiconductor device comprising:
a substrate;
an epitaxial semiconducting structure formed on said substrate;
a polycrystalline semiconducting structure; and
means for forming a first semiconducting junction between said epitaxial semiconductor structure and said polycrystalline semiconducting structure, said semiconducting junction having an area having at least one lateral dimension less than about 75 nanometers.

34. The semiconductor device in accordance with claim 33, further comprising: means for forming a second semiconducting junction between said epitaxial semiconductor layer and said substrate, said second semiconducting junction having an area having at least one lateral dimension less than about 75 nanometers.

35. A method for forming nanoscale semiconductor junctions comprising:
creating an epitaxial semiconducting layer including a dopant of a first polarity formed on a complementary doped semiconductor substrate;
creating an imprint layer on said epitaxial semiconducting layer;
urging a nanoimprinter toward said imprint layer;
removing selective portions of said epitaxial semiconducting layer forming an epitaxial semiconducting structure having an area having at least one lateral dimension less than about 75 nanometers;
creating a dielectric layer over said epitaxial semiconducting structure;
co-planarizing said dielectric layer to substantially the same thickness as said epitaxial semiconducting structure;
creating a polycrystalline semiconducting layer including a dopant of a second polarity over said epitaxial semiconducting layer and said dielectric layer;
removing selective portions of said polycrystalline semiconducting layer; and
forming a polycrystalline semiconducting structure having an area having at least one lateral dimension less than about 75 nanometers by selectively removing portions of said polycrystalline semiconducting layer.

36. A bipolar junction transistor created by the method of claim 35.

37. A method for forming nanoscale semiconductor junctions comprising:
creating an imprint layer on an epitaxial semiconducting layer;
urging a nanoimprinter toward said imprint layer;
removing selective portions of said epitaxial semiconducting layer;
forming an epitaxial semiconducting structure having an area having at least one lateral dimension less than about 75 nanometers; and
forming a first semiconducting junction having an area having at least one lateral dimension less than about 75 nanometers.

38. The method in accordance with claim 37, further comprising creating said epitaxial semiconducting layer on a complementary doped semiconductor substrate, wherein said epitaxial semiconducting layer includes a dopant of a first polarity.

39. The method in accordance with claim 38, further comprising creating a dielectric layer between said substrate and said epitaxial semiconducting layer.

40. A bipolar junction transistor created by the method of claim 37.

41. The method in accordance with claim 37, further comprising:
creating a first planarizing dielectric layer over said epitaxial semiconducting structure;
co-planarizing said first planarizing dielectric layer to substantially the same thickness as said epitaxial semiconductor structure;
creating a second semiconducting layer including a dopant of a second polarity over said epitaxial semiconducting layer and said first planarizing dielectric layer;
creating a second imprint layer on said second semiconducting layer;
urging a nanoimprinter toward said second imprint layer;
removing selective portions of said second semiconducting layer; and
forming a second semiconducting structure having an area having at least one lateral dimension less than about 75 nanometers.

42. The method in accordance with claim 41, further comprising forming a second semiconducting junction having an area having at least one lateral dimension less than about 75 nanometers.

43. A bipolar junction transistor created by the method of claim 41.

44. The method in accordance with claim 41, wherein creating a second semiconducting layer further comprises creating a doped polysilicon layer.

45. The method in accordance with claim 41, wherein forming said epitaxial semiconductor structure further comprises forming a plurality of epitaxial semiconducting lines substantially parallel to each other, and forming said second semiconducting structure further comprises forming a plurality of second semiconducting lines substantially parallel to each other, and at a predetermined angle to said plurality of epitaxial semiconducting lines.

46. The method in accordance with claim 37, further comprises removing a recessed portion.

47. The method in accordance with claim 37, further comprises creating an etch mask over portions of said imprinting layer and portions of said epitaxial semiconducting layer.

48. The method in accordance with claim 47, further comprising removing said etch mask.

49. The method in accordance with claim 47, wherein creating said etch mask further comprises:
creating a diffusion barrier over portions of said imprinting layer and portions of said epitaxial semiconducting layer; and
creating and electrically conductive layer over said diffusion barrier.

50. The method in accordance with claim 47, further comprising forming an electrical contact to said epitaxial semiconducting layer utilizing said diffusion barrier and said electrically conductive layer.

51. The method in accordance with claim 37, further comprising removing said implant layer.

52. The method in accordance with claim 51, further comprising plasma cleaning an exposed surface of said epitaxial semiconducting layer.

53. The method in accordance with claim 37, wherein said urging a nonoimprinter further comprises heating said implant layer.

54. The method in accordance with claim 37, further comprising etching said epitaxial semiconducting layer.

55. The method in accordance with claim 37, wherein creating said imprinting layer further comprises depositing said imprinting layer utilizing inkjet deposition.

56. A method for forming nanoscale junctions comprising:
creating a doped epitaxial silicon layer, which has a thickness less than about 75 nanometers, on a doped silicon wafer;
urging a nanoimprinter toward an imprint layer removing selective portions of said doped epitaxial silicon layer;
forming a semiconductor junction between said doped silicon wafer and said epitaxial silicon layer having an area having at least one lateral dimension less than about 75 nanometers;
forming a planarizing dielectric layer over said doped epitaxial silicon structure;
co-planarizing said planarizing dielectric layer to substantially the same thickness as said doped epitaxial silicon structure;
creating a second semiconducting layer over said epitaxial silicon structure and said planarizing dielectric layer, said semiconducting layer having a dopant opposite in polarity to said epitaxial silicon layer;
urging a nanoimprinter toward a second imprint layer;
removing selective portions of said second semiconducting layer; and
forming a second semiconductor junction between said doped epitaxial layer and said second semiconducting layer having an area having at least one lateral dimension less than about 75 nanometers.
